(19) United States
(12) Patent Application Publication
(10) Pub. No.: US 2002/0067195 A1
(43) Pub. Date: Jun. 6, 2002

(54) Adjustable phase shifter

(76) Inventor: Michael C. Fischer, Palo Alto, CA (US)

Correspondence Address: HEWLETT-PACKARD COMPANY, Intellectual Property Administration, P.O. Box 272400, Fort Collins, CO, 80527-2400, US

(21) Appl. No.: 09/726,622

(22) Filed: Dec. 1, 2000

(51) Int. Cl. H03K 3/00

(52) U.S. Cl. 327/237

(57) ABSTRACT

An apparatus and method for adjusting the phase of an output digital signal while maintaining the symmetry of the input signal. The apparatus includes an input waveform signal and a comparator having a positive feedback path to an input and an output. An adjustable resistor is connected along the positive feedback path to the output of the comparator and to the positive input of the comparator. The apparatus produces an output waveform signal shifted in phase from the input waveform signal with the same duty cycle as the input waveform signal.

### TECHNICAL FIELD

This invention relates to electronic circuits and more particularly to a circuit or device for adjusting the phase of a digital signal while maintaining the symmetry of the input signal.

### BACKGROUND ART

In communications and other signal processing applications, it is often necessary to adjust the phase of a signal so that it matches up with the phase of another signal, or to compensate for a time delay in the signal. This function has generally been performed by a monostable multi-vibrator, sometimes referred to as a “one-shot”, with an adjustable pulse-width. This approach to adjusting the phase of a signal yields an output pulse-width that varies as the delay is changed. In many cases this is an undesirable effect.

The present invention offers a simple, easy, and inexpensive means for changing the phase of a digital signal. It maintains the symmetry of the input signal, unlike the existing monostable vibrator. The present invention thus allows the time-of-occurrence of a signal transition to be delayed by an adjustable amount. Examples for implementation of this include aligning a clock signal to a data stream, or use as a phase modulator to vary the phase of a carrier signal in response to a modulating signal in a predictable, linear manner.

### SUMMARY OF INVENTION

What is described is an apparatus and a method for adjusting the phase of an output digital signal while maintaining the symmetry of the input signal. The apparatus includes an input waveform signal and a comparator having a positive feedback path to an input and an output. An adjustable resistor is connected along the positive feedback path to the output of the comparator and to the positive input of the comparator. The apparatus produces an output waveform signal shifted in phase from the input waveform signal with the same duty cycle as the input waveform signal.

Those skilled in the art will appreciate these and other advantages and benefits of various embodiments of the invention upon reading the following detailed description of a preferred embodiment with reference to the below-listed drawings.

### BRIEF DESCRIPTION OF DRAWINGS

FIG. 1 is a block diagram of one embodiment of an apparatus for adjusting the phase of an output digital signal while maintaining the symmetry of the input signal.

FIG. 2a is a diagram illustrating a small hysteresis for the input and output waveforms.

FIG. 2b is a diagram illustrating a large hysteresis for the input and output waveforms.

FIG. 3 is a flowchart of a method for adjusting the phase of an output digital signal while maintaining the symmetry of the input signal.

### DETAILED DESCRIPTION OF A PREFERRED EMBODIMENT

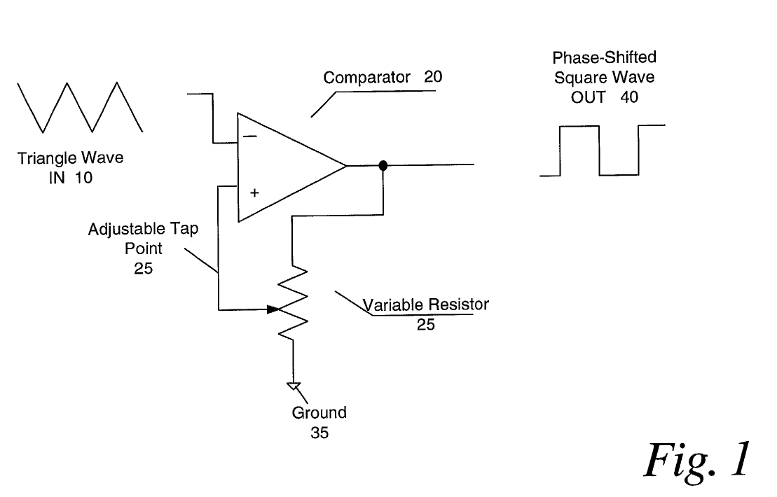

FIG. 1 is a circuit diagram of a circuit 100 for adjusting the phase of an output digital signal while maintaining the symmetry of the input signal in the output signal according to one embodiment of the present invention. The circuit 100 of the invention includes a comparator 20, having a positive and a negative input and an output; a variable resistor 30, connected to the output of the comparator 20 at one end and to ground 35 at the other; and an adjustable tap point 25 connected to the positive input of the comparator at one end and to the variable resistor 30 at the other end.

The circuit 100 also includes a waveform signal input 10 connected to the negative input of a comparator 20. Although the preferred input to the invention is a symmetric triangle waveform, any waveform, either symmetric or non-symmetric, including sine waves, may be processed by the invention.

The output of the circuit 100 is a phase-shifted square waveform signal output 40. As with the waveform signal input 10, the waveform signal output 40 may be other types of waveforms. The variable resistor 30 may be, for example, a rheostat, a potentiometer, or a field effect transistor, among others.

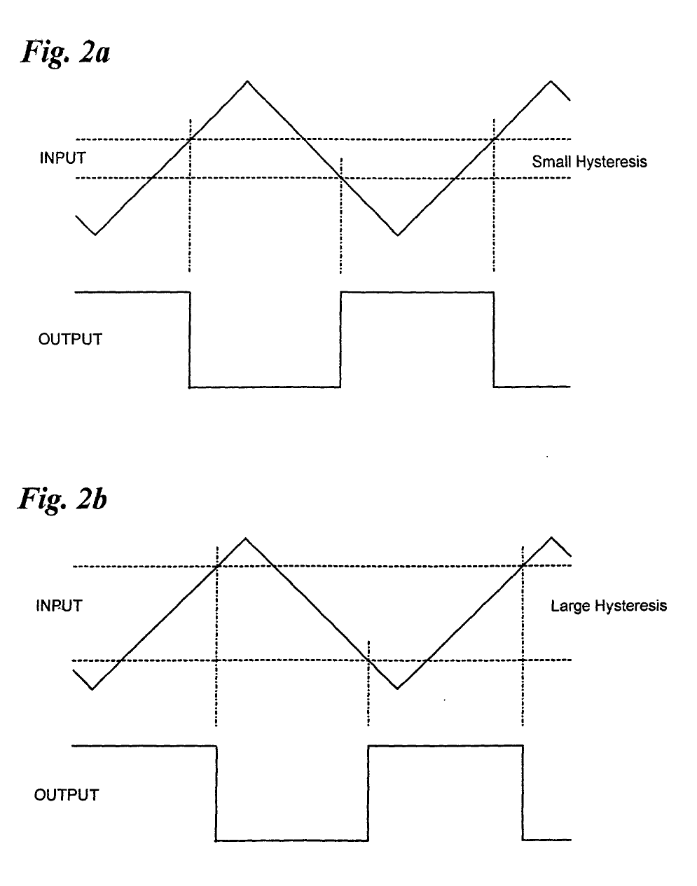

The adjustable tap point 25 is connected from the positive input of the comparator to the variable resistor 30. The adjustable tap point 25 may be manually manipulated to adjust the hysteresis of the triangle waveform signal input 10 and square waveform signal output 40. The hysteresis is determined by the intersection of the trailing and leading edges of the square waveform signal output 40 on the triangle waveform signal input 10, and is the difference between these two points, as seen in FIGS. 2a and 2b.

The shift in phase between the triangle waveform signal input 10 and the square waveform signal output 40 corresponds to the hysteresis caused by the adjustment of the variable resistor 30; as the hysteresis is adjusted, the phase is shifted. If the variable resistor 30 comprises a field effect transistor or other electronically variable resistance element, then the adjustable tap point 25, and thus also the hysteresis of the square waveform signal output 40, may be adjusted electronically.

The circuit 100 operates to adjust the phase of a signal by first accepting an waveform signal input 10 at the negative input of the comparator 20. This waveform signal input 10 is compared against a derived input signal (not shown) passed through the adjustable tap point 25 to the positive input of the comparator 20. The derived input signal passed through the adjustable tap point 25 is obtained from the effect of the variable resistor 30 that is connected to the output of the comparator 20 at one end and to ground 35 at the other. This establishes a positive feedback path between the output of the comparator 20 and the positive input of the comparator 20. The positive feedback path permits the introduction of the hysteresis resulting in a change in phase of the square waveform signal output 40. This feedback path, and therefore the phase difference between the waveform signal input 10 and the square waveform signal output 40, is adjustable by way of manipulation of the adjustable tap point 25 connected to the variable resistor 30.

With the tap point 25 set near the grounded end of its sliding range along the variable resistor 30, the hysteresis is brought to near zero and the square waveform signal output 40 is nearly in phase with respect to the waveform signal input 10. When the tap point 25 is adjusted to the upper limit of its sliding range, towards the output of the comparator 20, the resulting square waveform signal output 40 approaches 90 degrees out of phase from the waveform signal input 10.

It is noted that at a minimal hysteresis the square waveform signal output 40 is approximately in phase with the waveform signal input 10, and only a slight phase difference may be observed. Likewise, at the maximum amount of hysteresis the square waveform signal output 40 approaches being in quadrature with the waveform signal input 10.

FIG. 2a and FIG. 2b illustrate differing levels of hysteresis and the corresponding phase difference in the signals processed by the circuit 100. The input waveforms in both figures have the same phase, while the output waveform in FIG. 2a lags the input waveform (it is out of phase). As seen in FIG. 2b, however, the output waveform in FIG. 2b is even more out of phase, illustrating a phase delay of approximately 30 degrees more than the output in FIG. 2a. This is due to the change in hysteresis introduced by the invention.

The amount of phase change corresponds to the hysteresis introduced by the invention. As the amount of the hysteresis is adjusted, as described above with reference to FIG. 1, there is a corresponding change in the points on the waveform signal input 10 at which the comparator 20 changes state at its output. In other words, the points of intersection of the trailing edges and the leading edges of the square waveform signal output 40 move the same amount upward or downward as the variable resistor is adjusted, as seen in FIG. 2a and FIG. 2b. This causes the square waveform signal output 40 to maintain the same symmetry as the waveform signal input 10 when the phase of the square waveform signal output 40 is adjusted. For example, if the waveform signal input 10 is symmetrical (as shown in FIG. 2a or FIG. 2b), the square waveform signal output 40 will maintain this symmetry as the hysteresis is increased and the square waveform signal input's 10 trailing and leading edges are moved forward (i.e., delayed) by an equal amount.

As the hysteresis is increased, as in FIG. 2b, the points on the waveform signal input 10 at which the comparator 20 changes state at its output occurs at a later time in the same amount for both the leading edge and the trailing edge. Thus, the symmetry of the waveform signal input 10 is preserved in the square waveform signal output 40 even as the phase shift is accomplished.

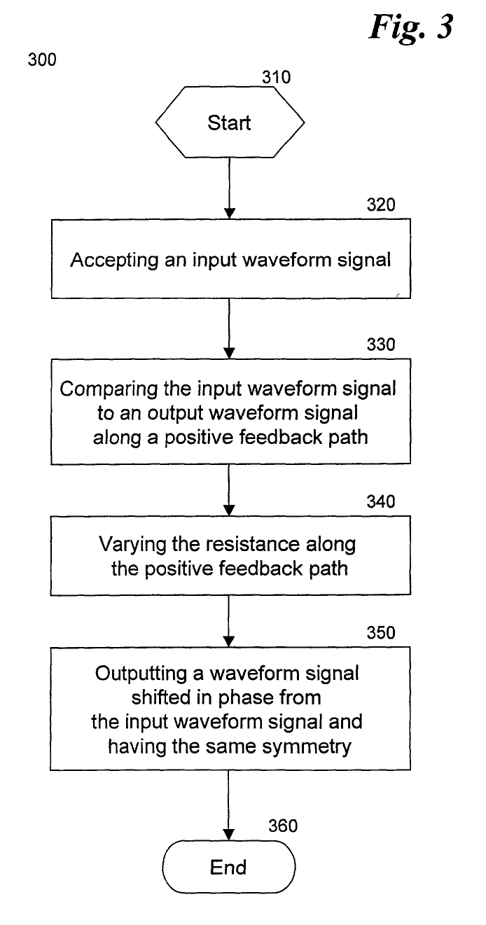

FIG. 3 is a flowchart of a method 300 according to the present invention for adjusting the phase of an output digital signal while maintaining the symmetry of the input signal. The method 300 comprises accepting or receiving 320-an input waveform signal. This input waveform signal is generally a symmetric triangle waveform signal, but may also be any other symmetric waveform signal, including a sine waveform signal.

The method 300 further comprises comparing 330 the input waveform signal to another waveform signal, or more particularly, an output waveform signal, received along a positive feedback path. The method 300 varies the resistance 340 along the positive feedback path in order to introduce hysteresis to the output waveform signal, and thereby adjust the phase of the output waveform signal. Varying the resistance 340 maybe accomplished either by manual adjustment or by automatic or electronic adjustment.

The method 300 produces an output waveform signal 350 shifted in phase from the input waveform signal. The output waveform signal produced maintains the symmetry of the input waveform signal.

The terms and descriptions used herein are set forth by way of illustration only and are not meant as limitations. Those skilled in the art will recognize that many variations are possible within the scope of the invention as defined in the following claims, and their equivalents, in which all terms are to be understood in their broadest possible sense unless otherwise indicated.

What is claimed is:

1. An apparatus for adjusting the phase of an input digital signal while maintaining the symmetry of the input signal, the apparatus comprising:
an input waveform signal, wherein the input waveform signal has a symmetry;
a comparator having a positive feedback path to a positive input and an output;
an adjustable resistor, connected to the output of the comparator and to the positive input of the comparator; and
an output waveform signal shifted in phase from the input waveform signal, wherein the output waveform signal has a symmetry that is the same as the input waveform signal duty cycle.

2. The apparatus of claim 1 wherein:
the input waveform signal is a symmetric triangle wave; and
the output waveform signal is a symmetric square wave.

3. The apparatus of claim 1 wherein the variable resistor further comprises:
a first terminal that is connected to the output of the comparator;
a second terminal that is grounded; and
an adjustable tap point that is connected to the positive input of the comparator.

4. The apparatus of claim 1 wherein the variable resistor is a rheostat.

5. The apparatus of claim 1 wherein the variable resistor is a potentiometer.

6. The apparatus of claim 1 wherein the variable resistor is a field effect transistor.

7. The apparatus of claim 1 wherein the variable resistor is an electronically adjustable resistor.

8. The apparatus of claim 1 wherein the variable resistor is an electronically adjustable potentiometer.

9. A method for adjusting the phase of an input digital signal while maintaining the symmetry of the input signal, the method comprising the steps of:
accepting an input waveform signal;
comparing the input waveform signal to an output waveform signal along a positive feedback path;
varying the resistance along the positive feedback path between the output and a positive input; and
outputting a waveform signal shifted in phase from the input waveform signal.

10. The method of claim 9 wherein varying step is performed manually.

11. The method of claim 9 wherein varying step is performed electronically.

12. A system for adjusting the phase of an input digital signal while maintaining the symmetry of the input signal, the system comprising:
a comparator having a negative input, a positive input, an output and a positive feedback path to the positive input;
an adjustable resistor, comprising:
a first terminal that is connected to the output of the comparator;
a second terminal that is grounded; and
an adjustable tap point that is connected to the positive input of the comparator;
an input waveform signal, connected to the negative input of the comparator, wherein the input waveform signal has a symmetry; and
an output waveform signal, output from the comparator output, wherein the output waveform signal is shifted in phase from the input waveform signal by adjusting the adjustable tap point and wherein the output waveform signal maintains a symmetry that is the same as the input waveform signal symmetry.

13. The system of claim 12, wherein:
the input waveform signal is a symmetric triangle wave; and
the output waveform signal is a symmetric square wave.

14. The system of claim 12, wherein the variable resistor is a rheostat.

15. The system of claim 12, wherein the variable resistor is a potentiometer.

16. The system of claim 12, wherein the variable resistor is a field effect transistor.

17. The system of claim 12, wherein the variable resistor is an electronically adjustable resistor.

18. The system of claim 12, wherein the variable resistor is an electronically adjustable potentiometer.
